(19) United States
(12) Patent Application Publication
(10) Pub. No.: US 2026/0246169 A1
(43) Pub. Date: Aug. 20, 2026

(54) ELECTRICAL CONNECTION MEMBER

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventor: Hironobu FUKUSHI, Mie (JP)

(21) Appl. No.: 19/165,143

(22) PCT Filed: Feb. 29, 2024
(86) PCT No.: PCT/JP2024/007463

§ 371 Date: Sep. 15, 2025

(30) Foreign Application Priority Data
Mar. 20, 2023 (JP) 2023-043744

(51) Int. Cl. H01R 9/24; H02K 5/22

(52) U.S. Cl. CPC H01R 9/24; H01R 2201/10; H02K 5/225

(57) ABSTRACT

An electrical connection member includes a terminal, a housing for holding the terminal and a sealing material arranged between the terminal and the housing. The housing contains at least one of a polyester-based resin and a polyamide-based resin. The sealing material contains a thermoplastic polymer, is soluble or swelling to both hexafluoroisopropanol and m-cresol and has a mass change rate of less than 20% when being immersed in lubricating oil at 100° C. for 8 hours.

### TECHNICAL FIELD

The present disclosure relates to an electrical connection member.

### BACKGROUND

It may become problematic that water intrudes into the inside of a device having an electrical connection member mounted thereon through a gap between a housing and a terminal in the electrical connection member such as a terminal block, in which the terminal is held in the housing made of resin. In such a case, it is required to suppress the passage of a liquid in a location between the housing and the terminal by imparting sealability to the electrical connection member. A method for devising a constituent material of a housing and the structure of a terminal (Patent Document 1), a method for filling a potting material into a housing (Patent Document 2), a method for sealing between a housing and a terminal by arranging a sealing material (Patent Document 3, 4) and the like can be cited as a method for imparting sealability to an electrical connection member.

According to the method using the sealing material, out of the above methods, sealability can be imparted to the electrical connection member without designing the terminal into a special structure or providing a part for accommodating the potting material in the housing. A rubber-based adhesive is used as the sealing material in Patent Document 3. The rubber-based adhesive is cured by vulcanization. Besides, a thermosetting polymer may be used as the sealing material. On the other hand, in Patent Document 4, a thermoplastic elastomer resin composition containing an acid-modified styrene-based elastomer, a syndiotactic polystyrene, a hydrogenated dicyclopentadiene at a predetermined ratio is used as the sealing material.

### PRIOR ART DOCUMENT

### Patent Document

Patent Document 1: JP 2016-085874 A
Patent Document 2: JP 2002-270283 A
Patent Document 3: International Publication No. WO 2017/154543
Patent Document 4: International Publication No. WO 2011/019026

### SUMMARY OF THE INVENTION

### Problems to be Solved

As described above, the arrangement of the sealing material between the housing and the terminal in the electrical connection member is effective in suppressing water intrusion into the inside of the device provided with the electrical connection member. Simultaneously, if lubricating oil is used inside that device, the sealing material exhibits sealability also to the lubricating oil and it can be expected that the leakage of the lubricating oil to the outside of the device via the gap between the housing and the terminal is suppressed. For example, in an automotive vehicle to be driven by a motor, the motor is provided with a terminal block and power is transmitted to the motor from an inverter via that terminal block. In the terminal block of this type, a sealing material may be provided between a housing and a terminal (busbar) to suppress the intrusion of moisture such as rainwater into the motor and suppress the leakage of lubricating oil filled in the motor.

If a terminal block is provided in a device containing lubricating oil such as a motor, a sealing material is placed in contact with the lubricating oil in the motor. If the sealing material is arranged in a location in contact with the lubricating oil, it is desired that high sealability is exhibited even if the sealing material is in contact with the lubricating oil. However, even a sealing material exhibiting high sealability in a state not in contact with the lubricating oil does not necessarily function to exhibit high sealability in a state in contact with the lubricating oil.

In view of the above, it is aimed to provide an electrical connection member having a sealing material arranged between a terminal and a housing and capable of maintaining high sealability even in a situation where the sealing material is in contact with lubricating oil.

### Means to Solve the Problem

The present disclosure is directed to an electrical connection member with a terminal, a housing for holding the terminal and a sealing material arranged between the terminal and the housing, the housing containing at least one of a polyester-based resin and a polyamide-based resin, and the sealing material containing a thermoplastic polymer, being soluble or swelling to both hexafluoroisopropanol and m-cresol and having a mass change rate of less than 20% when being immersed in lubricating oil at 100° C. for 8 hours.

### Effect of the Invention

The electrical connection member according to the present disclosure is an electrical connection member having the sealing material arranged between the terminal and the housing and capable of maintaining high sealability even in a situation where the sealing material is in contact with the lubricating oil.

### BRIEF DESCRIPTION OF THE DRAWINGS

FIGS. 1A and 1B are respectively a side view and a section showing a terminal block as an electrical connection member according to one embodiment of the present disclosure.

FIG. 2 is a side view showing an adhesion test piece.

FIGS. 3A and 3B are respectively a perspective view and a section showing a sealing test piece and FIG. 3C is a diagram showing a method for implementing a sealing test.

### DETAILED DESCRIPTION TO EXECUTE THE INVENTION

### Description of Embodiments of Present Disclosure

First, embodiments of the present disclosure are described. The electrical connection member of the present disclosure is configured as follows.

[1] The electrical connection member of the present disclosure is provided with a terminal, a housing for holding the terminal and a sealing material arranged between the terminal and the housing, the housing containing at least one of a polyester-based resin and a polyamide-based resin, and the sealing material containing a thermoplastic polymer, being soluble or swelling to both hexafluoroisopropanol and m-cresol and having a mass change rate of less than 20% when being immersed in lubricating oil at 100° C. for 8 hours.

In the electrical connection member of the present disclosure having the above configuration, since the sealing material arranged between the housing and the terminal contains the thermoplastic polymer, high adhesiveness to the housing is easily exhibited as compared to the case where the sealing material is made of polymer to be cured by vulcanization or thermosetting polymer. This is because, if the sealing material containing the thermoplastic polymer is arranged on a surface of the terminal and the housing is formed by molding or the like in a location including a surface of the sealing material while heating is appropriately performed, the sealing material is softened or melted by heat and strongly adhered not only to the terminal, but also to the housing by way of cooling. Further, since being soluble or swelling to both hexafluoroisopropanol and m-cresol, the sealing material exhibits high adhesiveness to the housing. The polyester-based resin and the polyamide-based resin as constituent materials of the housing are also materials exhibiting solubility and swellability to hexafluoroisopropanol and m-cresol and, and the sealing material has high compatibility with the constituent materials of the housing. As just described, since the sealing material exhibits high adhesiveness to the housing, high sealability is obtained in the electrical connection member and the transmission of water and the lubricating oil via a location between the housing and the terminal can be effectively suppressed. Further, since the sealing material exhibits high adhesiveness to the housing, high sealability by the sealing material can be maintained even if the sealing material is heated to a high temperature.

Further, since the sealing material constituting the electrical connection member of the present disclosure has the mass change rate of less than 20% when being immersed in the lubricating oil at 100° C. for 8 hours, a change due to dissolution, swelling or the like hardly occurs even if the sealing material is in contact with the lubricating oil having a high temperature. Thus, even if the electrical connection member is used in an environment where the sealing material is in contact with the lubricating oil, a situation where high adhesiveness of the sealing material to the housing is reduced due to the lubricating oil hardly occurs and a state having high sealability is maintained. Thus, the electrical connection member of the present disclosure can be suitably utilized as a constituent member of a device containing lubricating oil or a device used in an environment where lubricating oil is present.

[2] In [1] described above, a melting point of the sealing material may be 150° C. or higher. Then, even if the electrical connection member is used in an environment where a high temperature of 150° C. is reached, high sealability can be maintained by avoiding a reduction in sealability due to denaturation occurring at or near the melting point of the sealing material such as the elution of the sealing material. Since a large current is supplied in a motor for automotive vehicle, a terminal block is easily heated to a high temperature, but high sealability can be maintained even at a high temperature, whereby the electrical connection member of the present disclosure can be suitably used in an environment where a high temperature is reached.

[3] In [1] or [2] described above, the sealing material may contain a thermoplastic elastomer as the thermoplastic polymer. Then, since the sealing material is flexible, deterioration due to a thermal shock hardly occurs and a state having high sealability is easily maintained even if the electrical connection member is used in an environment where a temperature change is large.

[4] In any one of [1] to [3] described above, the sealing material may contain at least one of a polyurethane-based resin, a polyester-based resin and a polyamide-based resin as the thermoplastic polymer. Since these types of resins exhibit high adhesiveness to the housing containing at least one of the polyester-based resin and the polyamide-based resin and are hardly changed by the lubricating oil, these can be suitably used as the constituent materials of the sealing material.

[5] In any one of [1] to [4] described above, the housing may contain at least one of a polybutylene terephthalate, a nylon 6T and a nylon 9T. These types of resins have high mechanical strength and oil resistance, and can be suitably used to constitute the housing.

[6] In any one of [1] to [5] described above, the electrical connection member may be configured as a terminal block for a motor. The terminal block of the motor is a member to be held in contact with lubricating oil filled in the motor and gets hot by energization to the motor. However, the electrical connection member of the present disclosure can maintain high sealability even in an environment where the electrical connection member is in contact with the lubricating oil having a high temperature, whereby the electrical connection member can be suitably utilized as the terminal block of the motor.

### DETAILS OF EMBODIMENT OF PRESENT DISCLOSURE

Hereinafter, an electrical connection member according to one embodiment of the present disclosure is described in detail using the drawings. Various properties are values measured at room temperature in an atmosphere below unless otherwise specified.

Further, in this specification, polymers include those having a relatively low degree of polymerization such as oligomers.

### <Structure of Electrical Connection Member>

The electrical connection member of the present disclosure includes a terminal, a housing for holding the terminal and a sealing material arranged between the terminal and the housing. The electrical connection member is not particularly limited to a special type if the electrical connection member includes the terminal and the housing and the sealing material can be arranged between the terminal and the housing as just described, and a terminal block, a connector and the like can be illustrated as such. A terminal block is described below as a preferred example of the electrical connection member.

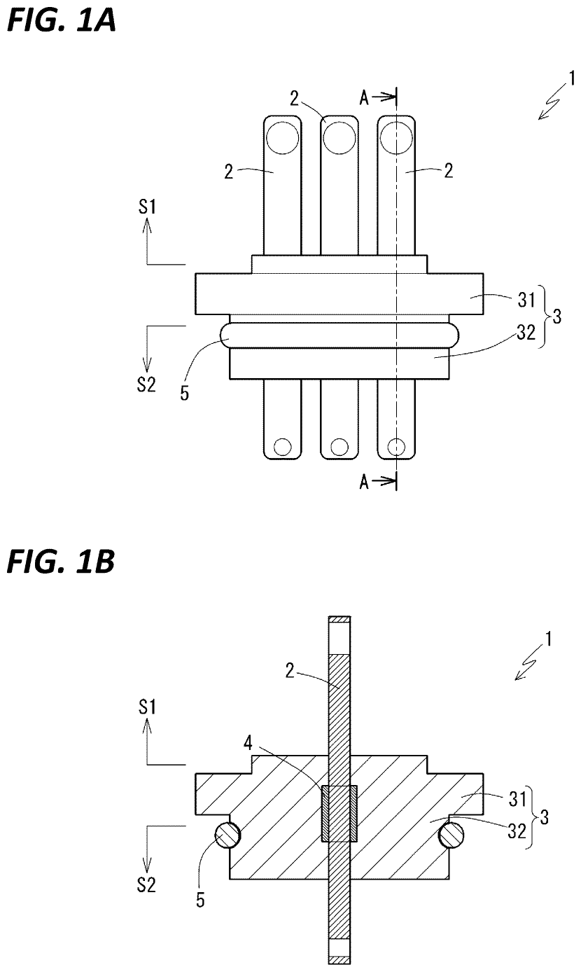

A terminal block 1 as an electrical connection member according to one embodiment of the present disclosure is schematically shown in FIGS. 1A and 1B. FIG. 1A is a side view and FIG. 1B is a section showing a cross-section along A-A in FIG. 1A. The terminal block 1 includes one or more (here, three) terminals (busbars) 2 and a housing 3. A sealing material 4 is arranged in a location between each terminal 2 and the housing 3. Further, optionally, a rubber ring 5 is arranged on the outer periphery of the housing 3.

The terminal (busbar) 2 is configured as a rod-like or plate-like member made of metal. In the shown form, the terminal 2 is configured as a plate piece including connection holes for wire connection on both ends. A constituent material of the terminal 2 is not particularly limited. A metal material such as copper, copper alloy, aluminum, aluminum alloy, iron or iron alloy or a material having a coating layer made of another metal such as a plating layer made of tin or tin alloy formed on the surface of one of those metal materials can be suitably used. A material having a plating layer made of tin or tin alloy formed on the surface of a base material made of copper or copper alloy can be particularly suitably used.

The housing 3 holds the terminal 2 by surrounding the outer periphery of the terminal 2 at least in a partial region of the terminal 2. In the shown form, the housing 3 integrally includes a block-like holding portion 32 and a flat plate-like flange portion 31. The holding portion 32 is a part for holding the terminals 2 and each terminal 2 is embedded in the holding portion 32 of the housing 3 in a middle region in a longitudinal direction. The holding portion 32 collectively holds the three terminals 2 arranged in parallel while being spaced apart from each other. The flange portion 31 functions as a mounting portion in mounting the terminal block 1 on a device or the like.

The housing 3 is made of a material containing at least one of a polyester-based resin and a polyamide-based resin. Since the polyester-based resin and the polyamide-based resin are high in mechanical strength and also high in heat resistance, these can be suitably used as a constituent material of the housing 3. At least one of the polyester-based resin and the polyamide-based resin may constitute preferably 50% by mass, more preferably 90% by mass or most preferably 100% by mass of a polymer material constituting the housing 3. Polybutylene terephthalate (PBT) can be suitably used as the polyester-based resin. Nylon 6T (PA6T), nylon 9T (PA9T), nylon 66 (PA66), nylon 610 (PA610) and nylon 612 (PA612) can be suitably used as the polyamide-based resin. The constituent material of the housing 3 may contain additives such as an anti-aging agent as appropriate in addition to the polymer material such as the polyester-based resin and the polyamide-based resin.

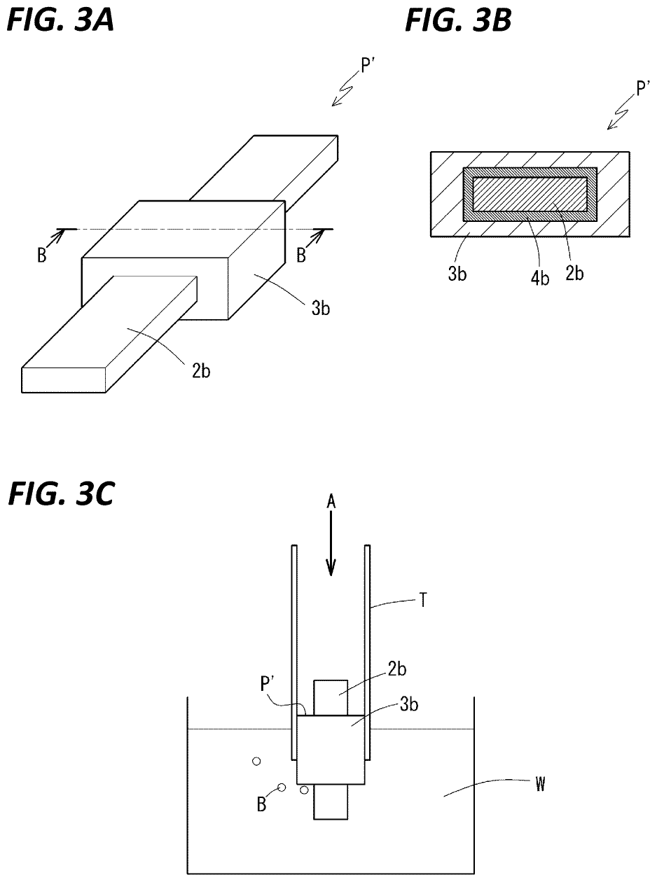

The sealing material 4 is made of a material containing a thermoplastic polymer different from the constituent material of the housing 3. The sealing material 4 is arranged between the terminal 2 and the housing 3 to seal a space between the terminal 2 and the housing 3. The sealing material 4 may be provided in an entire region between the terminal 2 and the housing 3 or may be provided only in a partial region as in the shown form. In the shown form, the sealing material 4 is arranged to surround the entire periphery of the terminal 2 (see FIG. 3B) in a partial region along the longitudinal direction of the terminal 2, out of a region where the terminal 2 is embedded in the housing 3. The sealing material 4 is arranged to seal the space between the terminal 2 and the housing 3 to block communication between a space where one end of the terminal 2 is arranged (outer space S1 in FIGS. 1) and a space where the other end is arranged (inner space S2 in FIGS. 1).

The sealing material 4 functions to suppress a movement of a liquid such as water between the outer space S1 and the inner space S2 of the terminal block 1 through a gap between the terminal 2 and the housing 3 by sealing the space between the terminal 2 and the housing 3. That is, sealability is imparted to the terminal block 1 by the sealing material 4. Since the constituent material of the sealing material 4 has predetermined properties, the sealing material 4 exhibits high sealability. The constituent material of the sealing material 4 is described in detail later.

The rubber ring 5 is a member in the form of an O-ring made of an elastic material such as rubber, and disposed on the outer periphery of the housing 3. In the shown form, the rubber ring 5 is disposed at a position near a boundary to the flange portion 31, out of the holding portion 32 of the housing 3. The rubber ring 5 functions to suppress a movement of a liquid such as water between the outer space S1 and the inner space S2 via a gap between a wall surface of a device or the like and the flange portion 31 when the terminal block 1 is mounted on the device or the like.

The terminal block 1 can be used as a member for establishing electrical connection between the outer space S1 and the inner space S2 by being mounted on various devices. The device may be provided with an opening, into which the terminal block 1 can be mounted, a location of the terminal block 1 corresponding to the inner space S2 may be inserted into that opening and the terminal block 1 may be fixed to the device at the flange portion 31. A location of the terminal block 1 corresponding to the outer space S1 projects outward from the device. Since the terminal block 1 has sealability, a movement of a liquid between the inside and outside of the device via the terminal block 1 hardly occurs in such a state mounted on the device. That is, the movement of the liquid via the gap between the terminal 2 and the housing 3 is suppressed by the sealing material 4 and the movement of the liquid via a gap between the housing 3 and a device wall surface is suppressed by the rubber ring 5. Particularly, the intrusion of moisture such as rainwater into the inside of the device from the outside of the device is effectively suppressed. Further, this is also effective in suppressing a phenomenon that a liquid arranged inside the device such as lubricating oil leaks to the outside of the device.

The type of the device, on which the terminal block 1 is mounted, is not particularly limited. However, since the sealing material 4 is made of the material capable of maintaining high sealability even in a state in contact with lubricating oil, the terminal block 1 can be suitably applied to a device, which uses lubricating oil and in which water intrusion is unfavorable, from the perspective of effectively utilizing those properties. A motor, particularly a motor for vehicle can be illustrated as the device of that type. In the motor for vehicle, the terminal block 1 is required to have high sealability due to a need to suppress the intrusion of moisture in an outdoor environment such as rainwater. Further, lubricating oil is normally filled inside the motor and sealability for lubricating oil is also required.

A method for manufacturing the terminal block 1 is not particularly limited, and either one of a method for assembling independently formed members and a method by integral molding may be used. However, integral molding can be suitably applied. In the case of performing integral molding, the sealing material 4 is first arranged at predetermined positions on the outer peripheral surfaces of the terminals 2. At this time, the constituent material of the sealing material 4 may be heated and melted, and arranged in desired locations. A technique such as molding by a mold, coating, dripping or the like can be used to arrange the sealing material 4 in the predetermined locations. After the sealing material 4 is arranged in the predetermined locations, the sealing material 4 is heated to or higher than a melting point or a softening temperature and, in that state, the housing 3 is formed in a predetermined region including a location surrounding the sealing material 4. The housing 3 may be formed by molding using a mold. The rubber ring 5 may be appropriately mounted on the outer periphery of the formed housing 3.

In the above manufacturing method, when the sealing material 4 is arranged on the surface of the terminal 2 made of metal, the sealing material 4 is firmly adhered to the surface of the terminal 2 by the constituent material of the sealing material 4 in the melted or softened state contacting the surface of the metal material. Further, when the housing 3 is formed, the constituent material of the housing 3 is molded on the surface of the sealing material 4 with the sealing material 4 heated to the melting point or the softening temperature, whereby fusion occurs between the sealing material 4 and the housing 3 and the sealing material 4 is adhered to the housing 3. The sealing material 4 may be heated to the melting point or the softening temperature by the heat of the constituent material of the housing 3 when the housing 3 is molded or by being heated separately before the housing 3 is molded. Preferably, a heating temperature may be so set that the sealing material 4 is heated to a temperature equal to or higher than the melting point and melted from the perspective of obtaining high adhesion strength between the sealing material 4 and the housing 3.

### <Constituent Material of Sealing Material>

Next, the constituent material of the sealing material 4 used in the terminal block (electrical connection member) 1 according to this embodiment is described.

As described above, the sealing material 4 used in this embodiment contains the thermoplastic polymer. Since the sealing material 4 contains the thermoplastic polymer, the entire constituent material of the sealing material 4 exhibits thermoplasticity. Since the sealing material 4 is made of the thermoplastic material, high adhesion strength can be obtained between the sealing material 4 and the terminal 2 and the housing 3. Particularly, high adhesiveness is more easily obtained than in the case of using not a thermoplastic polymer, but a polymer to be cured by vulcanization or a thermosetting polymer for the following reason. In the case of using the polymer to be cured by vulcanization or the thermosetting polymer, the housing 3 is formed on the surface of the already cured sealing material, wherefore it is difficult to obtain firm adhesion on a microscopic scale. On the contrary, in the case of using the thermoplastic polymer, fusion occurs between the sealing material 4 and the constituent material of the housing 3 and adhesion is obtained by microscopic interaction by forming the housing 3 in a state where the sealing material 4 arranged on the surface of the terminal 2 is temporarily melted or softened by heating as described above for the manufacturing method of the terminal block 1. From the perspective view of enhancing an effect of improving adhesiveness, the thermoplastic polymer may constitute preferably 50% by mass, more preferably 90% by mass or most preferably 100% by mass of the polymer material constituting the sealing material 4. Further, various properties described as properties of the entire constituent material of the sealing material 4 below are preferably provided also as properties of the single thermoplastic polymer constituting the sealing material 4.

Further, the sealing material 4 used in this embodiment exhibits particularly high adhesiveness since having predetermined solubility and swelling properties. Specifically, the sealing material 4 is soluble or swellable to both hexafluoroisopropanol (HFIP) and m-cresol. Here, solubility and swellability to HFIP and m-cresol are indices indicating compatibilities with the polymer materials constituting the sealing material 4 and the housing 3. Out of various organic solvents, HFIP has a relatively small solubility parameter (SP value) and m-cresol has a large SP value. The polyester-based resin and the polyamide-based resin, which are materials constituting the housing 3, are easily soluble or swellable to both HFIP and m-cresol. Actually, it is confirmed in Example that PBT, PA6T and PA9T are soluble or swellable to both HFIP and m-cresol. In particular, it is confirmed that PBT is swellable to both of those solvents and PA6T and P9T are soluble to both of those solvents. That two different types of materials, i.e. the constituent material of the sealing material 4 and the constituent material of the housing 3 are soluble or swellable to the same solvents indicates that those two types of materials are highly compatible with each other and are mixed with each other on a molecular level when being brought into contact in a fluidal state. That is, it indicates that high adhesiveness is obtained on a fusion interface. Since the constituent material of the sealing material 4 is soluble or swellable to both HFIP and m-cresol in this embodiment, the sealing material 4 exhibits high adhesiveness to the housing 3 made of the material likewise exhibiting solubility or swellability to those solvents. Among others, if at least one, preferably both, of the constituent material of the sealing material 4 and that of the housing 3 is/are soluble to both HFIP and m-cresol, particularly high compatibility and adhesiveness are obtained between the sealing material 4 and the housing 3. The polyamide-based resin such as PA6T, PA9T, which is soluble to both HFIP and m-cresol, can be particularly suitably used for the housing 3.

Here, HFIP and m-cresol are used as the solvents, which indicate the compatibility between the sealing material 4 and the housing 3, because both HFIP and m-cresol are solvents having SP values separated from each other to a certain extent and, in addition, having intramolecular polarization, and compatibilities with the polyester-based resin and the polyamide-based resin, which are polymers having polarization, are easily precisely evaluated. Note that, in this specification, that a certain material is soluble to a certain solvent indicates that, when pellets of that material are immersed in that solvent, the pellets enter a state uniform with the solvent to become invisible. Further, that a certain material is swellable to a certain solvent indicates that, when pellets of that material are immersed in that solvent, the mass of the pellets increases. A mass increase indicates, for example, a state where the mass exceeds 1.1 times as much as the mass before immersion in the solvent. 0.3 g of the sealing material 4 is mixed with 10 ml of a solvent and left at room temperature for 1 week can be illustrated as determination conditions for dissolution and swelling as in Example later.

The sealing material 4 used in this embodiment has high oil resistance in addition to having the solubility and swelling properties described above. Specifically, a mass change rate (hereinafter, referred to as an oil resistance mass change rate) of the sealing material 4 is less than 20% when the sealing material 4 is immersed in lubricating oil at 100° C. for 8 hours. Here, the oil resistance mass change rate of the sealing material 4 indicates a mass change amount by immersion, i.e. a decrease amount or an increase amount, by an absolute value on the basis of a mass before immersion in the lubricating oil. The oil resistance mass change rate of less than 20% indicates that the sealing material 4 hardly undergoes a change such as a mass decrease due to dissolution or a mass increase due to swelling even if the sealing material 4 is in contact with lubricating oil having a high temperature. That is, this indicates that the sealing material 4 has high oil resistance and a reduction in adhesiveness due to the lubricating oil and the transmission of the lubricating oil hardly occur. More preferably, the oil resistance mass change rate may be 10% or less, further 7% or less. A lower limit is not particularly provided for the oil resistance mass change rate, but is roughly 1% or more. The specific type of the lubricating oil used in the evaluation of the oil resistance mass change rate is not particularly limited, but it is preferred to use lubricating oil to be possibly contacted by the sealing material 4 such as lubricating oil used in the device, on which the terminal block 1 is mounted. For example, an ATF (Automatic Transmission Fluid) is preferably used as the lubricating oil. The ATF may be filled in a motor for automative vehicle.

As described above, the sealing material 4 is highly adhesive not only to the terminal 2, but also to the housing 3 since the sealing material 4 contains the thermoplastic polymer and is soluble or swellable to HFIP and m-cresol. Thus, a movement of a liquid such as water between the outer space S1 and the inner space S2 via the gap between the housing 3 and the terminal 2 is firmly suppressed in the terminal block 1 and high sealability is imparted to the terminal block 1. As a result, it is effectively suppressed in the device having the terminal block 1 mounted thereon that moisture such as rainwater intrudes from outside through the location between the housing 3 and the terminal 2. This is highly effective also in suppressing the leakage of a liquid inside the device such as lubricating oil to the outside of the device. Further, since the sealing material 4 is highly adhesive to the terminal 2 and the housing 3, high sealability can be maintained due to the adhesiveness of the sealing material 4 even in an environment where the sealing material 4 gets hot. Further, since the oil resistance mass change rate of the sealing material 4 is suppressed to be less than 20%, a state where the sealing material 4 is strongly adhered to the terminal 2 and the housing 3 and exhibits high sealability as just described can be maintained even in an environment where the sealing material 4 is in contact with lubricating oil having a high temperature. Since the sealing material 4 has these properties, high sealability is imparted to the terminal block 1 according to this embodiment by the sealing material 4 and that sealability is maintained even in a hot environment and an environment where the sealing material 4 is in contact with the lubricating oil.

As described above, the sealing material 4 is soluble or swellable to HFIP and m-cresol, whereby high adhesiveness to the housing 3 is exhibited and an adhesion strength of, e.g. 0.5 MPa or more can be obtained between the housing 3 and the sealing material 4. More preferably, the adhesion strength may be 3 MPa or more. An upper limit of the adhesion strength is not particularly designated, but is roughly 10 MPa or less. The adhesion strength of the sealing material 4 to the housing 3 may be, for example, evaluated as a shear adhesion strength by conducting a tensile shear test for an adhesion test piece in which the sealing material 4 is sandwiched between a plate molded from the constituent material of the housing 3 and a copper plate as in Example later.

Further, the sealing material 4 preferably has a melting point of 150° C. or higher. Then, the sealing material 4 has high heat resistance and the adhesiveness thereof is hardly reduced due to elution or denaturation even if the sealing material 4 is placed in a high-temperature environment. Particularly, even if the sealing material 4 has hydrolyzability, hydrolysis possibly occurring when the sealing material 4 is heated to or near the melting point in a moisture absorption state and the deterioration of the sealing material 4 can be suppressed. As just described, since the sealing material 4 has a high melting point, the terminal block 1 is particularly suitable for heated use. For example, since a large current is supplied via the terminal block 1 in a motor for automotive vehicle, the terminal block 1 easily gets hot. The melting point of the sealing material 4 is more preferably 155° C. or higher. An upper limit is not particularly provided for the melting point of the sealing material 4, but may be roughly 200° C. or lower in terms of molding by heating, ease of adhesion and the like.

A specific material for constituting the sealing material 4 is not particularly limited, but this material preferably contains a thermoplastic elastomer as the thermoplastic polymer. Since the thermoplastic elastomer is flexible, a thermal shock can be effectively mitigated. Thus, the sealing material 4 is hardly deteriorated by the thermal shock and, even if the terminal block 1 is used in an environment subject to a temperature change such as the inside of an automotive vehicle, high sealability by the sealing material 4 can be maintained. An elastomer is generally a polymer having a shear elastic modulus of roughly about 1 MPa to 200 MPa. Also in this embodiment, a thermoplastic elastomer having such a shear elastic modulus may be used. Particularly preferably, a thermoplastic elastomer having a shear elastic modulus of 150 MPa or less, further 100 MPa or less may be used.

Further, at least one of a polyurethane-based resin, a polyester-based resin and a polyamide-based resin can be suitably used as one type of the thermoplastic polymer for constituting the sealing material 4. Those resins easily exhibit high adhesiveness to the terminal 2 made of metal and the housing 3 containing the polyester-based resin or the polyamide-based resin and has high oil resistance. Here, elastomers are also included in the above various resins, and the sealing material 4 particularly preferably contains at least one of a polyurethane-based elastomer, a polyester-based elastomer and a polyamide-based elastomer as the thermoplastic polymer.

The sealing material 4 may contain various additives in addition to the polymer material such as the thermoplastic polymer. A silane coupling agent can be cited as a preferred example of the additive. Since the sealing material 4 contains the thermoplastic polymer, the sealing material 4 is highly adhesive to the terminal 2 by being arranged on the surface of the terminal 2 in a melted state. By adding the silane coupling agent to the sealing material 4, adhesiveness to the terminal 2 can be further enhanced. This is because the silane coupling agent forms stable chemical bonds to metal atoms on a metal surface. Note that a tackifier made of terpene phenolic resin also has a function of enhancing adhesiveness between the sealing material 4 and the metal surface, but is often low in oil resistance. From the perspective view of suppressing an influence on the oil resistance of the sealing material 4, the use of the silane coupling agent, which is a substance having high oil resistance, is more preferable than the use of the tackifier. A coloring pigment, a viscosity modifier, an anti-aging agent, an inorganic filler, a storage stabilizer, a dispersant and the like can be cited as additives other than the silane coupling agent.

### EXAMPLE

Example is described below. Here, relationships of properties of a sealing material and sealability were investigated. In this Example, the properties are evaluated at room temperature in an atmosphere unless otherwise specified.

### [Fabrication of Specimens]

The following materials were prepared as sealing materials.
Sealing material A1: Polyurethan-based resin—“Elastollan 1198A” produced by BASF.
Sealing material A2: Polyester-based resin—“ESTERARE-D42N” produced by Aronkasei Co., Ltd.
Sealing material A3: Polyamide-based resin—“VG TPA-2181” produced by Tsuno Co., Ltd.
Sealing material B1: Polystyrene-based resin—“ARVAS VF-A90NT” produced by Aronkasei Co., Ltd.
Sealing material B2: Polyester-based resin—“Pensel D-125” produced by Arakawa Chemical Industries, Ltd.
Sealing material B3: Polyolefin-based resin—“Milastomer A970B” produced by Mitsui Chemicals Inc.
Sealing material B4: Polyvinyl chloride-based resin—“HIPEX HX71DZ” produced by KRAIBURG TPE.

Any of the above materials has thermoplasticity and is a thermoplastic elastomer except the sealing material B2. Further, a shear elastic modulus of each material is 100 MPa or less.

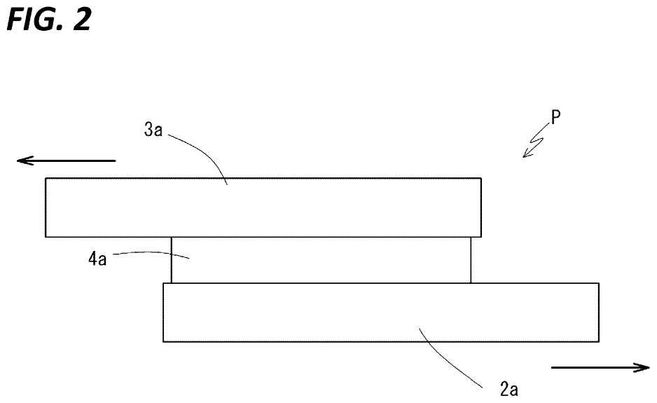

Further, using the above respective sealing materials, adhesion test pieces used for an adhesion test and sealing test pieces used for a sealing test were fabricated. A test piece having a structure shown in FIG. 2 was fabricated as the adhesion test piece. That is, an adhesion test piece P was fabricated in which a sheet body 4a made of the sealing material was sandwiched between a copper plate 2a and a resin plate 3a and adhered to the copper plate 2a and the resin plate 3a on both front and back surfaces respectively. To fabricate the adhesion test piece P, each sealing material was molded into a sheet having a thickness of 0.5 mm by heat press and cut out into a piece of 10 mm×10 mm. Subsequently, the cut-out sheet body 4a was arranged on the copper plate 2a (C1100 material) and heated at 200° C. for 20 minutes, thereby being adhered to the copper plate 2a. Further, the copper plate 2a having the sheet body 4a adhered thereto was set in a mold, PA6T (“HTN 54G35EF BK420” produced by Du Pont), which is a constituent material of a housing, was molded into a plate on a surface of the sheet body 4a to form the resin plate 3a. Molding was performed under conditions including a nozzle temperature of 320° C., a mold temperature of 140° C., an injection speed of 60 mm/s and a holding pressure of 40 MPa.

A test piece having a structure shown in FIGS. 3A and 3B was fabricated as the sealing test piece. FIG. 3A is a perspective view of a sealing test piece P′ and FIG. 3B is a section showing a cross-section along B-B in FIG. 3A. The sealing test piece P′ simulates a terminal block, the sealing material 4b is arranged in a partial region of the outer periphery of a model terminal 2b, and a housing 3b is formed to include a location covering the sealing material 4b. In fabricating this sealing test piece P′, a copper piece was prepared as the model terminal 2b. A size of the model terminal 2b was 12.0 mm×80.0 mm×1.6 mm. The sealing material 4b was adhered to cover the entire outer periphery in a partial region along a longitudinal direction of this model terminal 2b. At this time, the sealing material 4b was arranged and adhered at a predetermined position at a temperature higher than the melting point of each sealing material by 30° C. by molding. A width (dimension along the longitudinal direction of the model terminal 2b) of the covering region of the sealing material 4b was 5 mm and a thickness of a layer of the sealing material 4b was 1 mm. Further, the housing 3b was molded on the outer periphery of the model terminal 2b to include a region covering the entire sealing material 4b. A used material and conditions in molding the housing 3b were similar to those when the resin plate 3a was formed in the adhesion test piece P.

### [Evaluation of Properties]

Properties were evaluated for each of the sealing materials A1 to A3 and the sealing materials B1 to B4 by each of the following tests.

### (1) Solubility and Swelling Properties

A solubility and swelling test was conducted and the solubility and swelling properties of each sealing material, i.e. whether or not each sealing material was dissolved or swollen to a solvent, were evaluated. Specifically, 10 ml of HFIP or m-cresol was collected as a solvent into a glass container and 0.3 g of each sealing material in the form of pellets was mixed. After a mixture was left at room temperature for 1 week, whether or not the sealing material was dissolved was visually determined. At this time, the sealing material was determined to be dissolved if the pellets of the sealing material were uniformly dissolved in the solvent and a uniform mixture was formed at such a level that the pellets were visually unidentifiable. On the other hand, if the shape of the pellets could be visually distinguished, the sealing material was determined not to be dissolved. If dissolution did not occur, a mass change was obtained from masses before and after immersion in the solvent and the sealing material was determined to have swollen if the mass after immersion exceeded 1.1 times as much as the mass before immersion. The specimen having undergone dissolution was determined as “A”, the specimen having undergone swelling, but not undergone dissolution was determined as “B” and the specimen having undergone neither dissolution nor swelling was determined as “C”. Note that, actually, none of the tested sealing materials was determined as “B”.

The solubility and swelling test was conducted for each sealing material, and also conducted for each of the following materials serving as constituent materials of the housing in a method similar to the above method. Any of the materials was confirmed to exhibit solubility and swellability to both FPIP and m-cresol.
PBT: “CG7030” produced by Polyplastics—solubility and swelling properties: B
PA6T: “HTN 54G35EF BK420” produced by Du Pont—solubility and swelling properties: A
PA9T: “GENESTAR G1300H” produced by Kuraray Co., Ltd.—solubility and swelling properties: A

### (2) Oil Resistance Mass Change Rate

2 g of each sealing material was collected, and put into a container after the mass thereof was measured, and entirely immersed in lubricating oil (ATF “CVTF S-NS-3” produced by Shell Lubricant Japan K.K.). In this state, each sealing material was left at 100° C. for eight hours. Thereafter, the sealing material was taken out from the lubricating oil, and the mass of the sealing material was measured after the lubricating oil on the surface was wiped off. A change amount of the mass on the basis of the mass of the sealing material before immersion was calculated and set as an oil resistance mass change rate. The oil resistance mass change rate indicates a change rate of the mass without depending on a direction of change. In this Example, a change in a mass increasing direction was recorded as a positive value and a change in a mass decreasing direction is recorded as a negative value.

### (3) Melting Point

A melting point of each sealing material was measured by a DSC (differential scanning calorimetry) method. In measurement, a temperature range was 23° C. to 200° C. and a temperature rising rate was 100° C./min.

### (4) Adhesion Strength

An adhesion strength of the sealing material was measured by a tensile shear test, using the adhesion test piece P fabricated above. At this time, the adhesion test piece P was set in a tensile testing machine by holding the copper plate 2a and the resin plate 3a in locations where the sheet body 4a made of the sealing material was not adhered, and a tensile load in a shear direction was applied in parallel to a plate surface as indicated by an arrow in FIG. 2. In a tensile shear test, fracture occurred on an interface between the sheet body 4a and the copper plate 2a or on an interface between the sheet body 4a and the resin plate 3b. For the sealing material in which fracture occurred on the interface between the sheet body 4a and the resin plate 3a, a load at the time of that fracture was recorded as the adhesion strength of the sealing material to the resin plate 3a. For the sealing material in which fracture occurred on the interface between the sheet body 4a and the copper plate 2a, the adhesion strength of the sealing material to the resin plate 3a was recorded to be higher than a load at the time of that fracture (the load at the time of fracture is shown together with “>” in Table 1). A value obtained by dividing the tensile load when separation occurs on the interface between the sheet body 4a and the resin plate 3a by an adhesion area of the sheet body 4a to the resin plate 3a was set as the adhesion strength of the sealing material. If the adhesion strength is 0.5 MPa or more, adhesiveness can be regarded as good.

### (5) Sealing Test

A sealing test was conducted using the above fabricated sealing test pieces P′. Prior to the sealing test, two types of sealing test pieces P′ including those left at a high temperature and those gone through immersion in oil were prepared. The sealing test pieces P′ left at a high temperature were left at 150° C. for 2000 hours in an atmosphere. The sealing test pieces P′ immersed in oil were immersed in ATF (same as that used for the measurement of the oil resistance mass change rate) at 100° C. for 500 hours.

In conducting the sealing test, the sealing test piece P′ left at a high temperature or gone through immersion in oil was attached to the tip of a tube T as shown in FIG. 3C. At this time, a tube having an inner diameter substantially equal to an outer diameter of the housing 3b of the sealing test piece P′ was used as the tube T, the sealing test piece P′ was press-fit into the tip of the tube T in the location of the housing 3b, and the tube T was held in close contact with the housing 3b. In this way, a location from one end of the sealing test piece P′ to a midway part of the housing 3b was accommodated in a space in the tube T. Then, the tip of the tube T having the sealing test piece P′ attached thereto was immersed in water W stored in a water tank. The base end of the tube T was located outside the water W so that compressed air A could be introduced through that base end.

The compressed air A of 10 kPa (pressure was shown by a pressure difference from an atmospheric pressure) was introduced through the base end of the tube T for 30 seconds. During that time, whether or not bubbles were generated from a boundary part between the model terminal 2b and the housing 3b of the sealing test piece P′ was visually observed. The generation of the buttles B means that the location between the sealing material 4b and the housing 3b was not sufficiently sealed and the compressed air A leaked from that location. If the bubbles B did not leak, the pressure of the compressed air A was increased by 10 kPa each time and a step of determining whether or not the bubbles B were generated was similarly repeated. Then, the pressure of the compressed air A when the generation of the bubbles B started was recorded as a sealing pressure.

If the sealing pressure is less than 100 kPa, sealability was determined to be low (B). On the other hand, if the sealing pressure is 100 kPa or more and less than 200 kPa, sealability was determined to be sufficient (A). Further, if the sealing pressure is equal to or more than 200 kPa, sealability was determined to be particularly high (A+).

### [Evaluation Results]

Results of the respective evaluations are shown for the sealing materials A1 to A3, B1 to B4 in Table 1 below.

TABLE 1

| | | | Type of Sealing Material | | | | | | |
|---|---|---|---|---|---|---|---|---|---|
| | | | A1 | A2 | A3 | B1 | B2 | B3 | B4 |
| Solubility and | | HFIP | A | A | A | A | A | C | C |
| Swelling Properties | | M-Cresol | A | A | A | A | A | C | C |
| Oil Resistance Mass | | | 10 | 4.5 | 6.5 | 30 | 20 | 30 | 8.5 |
| Change Rate [%] | | | | | | | | | |
| Melting Point | | | 155 | 160 | 155 | 155 | 125 | 155 | 190 |
| [° C.] | | | | | | | | | |
| Adhesion Strength | | | >3 | >5 | >5 | 2 | 1 | 0 | 0 |
| [MPa] | | | | | | | | | |
| Sealing | Left at | Sealing | 200 or | 200 or | 200 or | 200 or | 160 | 10 | 10 |
| Test | High | Pressure | more | more | more | more | | | |
| | Temper- | [kPa] | | | | | | | |
| | ature | Determination | A+ | A+ | A+ | A+ | A | B | B |
| | | Result | | | | | | | |
| | After Oil | Sealing | 180 | 200 or | 200 or | 10 | 10 | 10 | 10 |
| | Immersion | Pressure | | more | more | | | | |
| | | [kPa] | | | | | | | |
| | | Determination | A | A+ | A+ | B | B | B | B |
| | | Result | | | | | | | |

According to Table 1, any of the sealing materials A1 to A3 and the sealing materials B1, B2 is soluble to both HFIP and m-cresol. Corresponding to that, an adhesion strength largely exceeding 0.5 MPa is obtained for PA6T. On the other hand, in the sealing materials B3, B4 neither soluble nor swelling to those solvents, the adhesion strength is 0 MPa. That is, (substantially) no adhesiveness is exhibited for PA6T.

Looking at the result of the sealing test after being left at a high temperature, sufficient sealability evaluated to be A+ or A is obtained for any of the sealing materials A1 to A3 and the sealing materials B1, B2 soluble to both HFIP and m-cresol and exhibiting high adhesiveness to PA6T. Particularly, high sealability evaluated to be A+ is obtained in the sealing materials A1 to A3 and B1 having a large adhesion strength of 2 MPa or more. In contrast to those, sealability after being left at a high temperature is low (B) in either of the sealing materials B3, B4 neither soluble nor swelling to HFIP and m-cresol and having low adhesiveness to PA6T. From these results, it is understood that, if the sealing material exhibits high adhesiveness to the constituent material of the housing based on an index that the sealing material is soluble to both HFIP and m-cresol, sufficient sealability can be maintained for the housing even if the sealing material is heated to a high temperature. Note that the sealing materials A1 to A3 are thought to have higher sealability after being left at a high temperature than the sealing material B2 because of a high melting point in addition to a large adhesion strength.

Next, focusing on the oil resistance mass change rate and the sealability after immersion in oil, high sealability determined to be A or A+ is obtained after immersion in oil in the sealing materials A1 to A3 having an oil resistance mass change rate below 20% in absolute value. Among them, in the sealing materials A2, A3 having the oil resistance mass change rate suppressed to or below 7%, particularly high sealability (A+) is obtained. On the other hand, the sealability after immersion in oil is evaluated to be low as B in the sealing materials B1 to B3 having the oil resistance mass change rate of 20% or more. The oil resistance mass change rate of the sealing material B4 is suppressed to be less than 20% by mass, but has an adhesion strength of 0 MPa and is (substantially) not adhered to the housing. Thus, the sealability after immersion in oil is evaluated to be low as B. The sealing material B1 has a large adhesion strength of 2 MPa and maintains high sealability even after being left at a high temperature in the atmosphere, but has a large oil resistance mass change rate and the sealability thereof is thought to be reduced by way of immersion in oil due to low oil resistance. From these results, it can be said that the sealing material needs to have high oil resistance so that the oil resistance mass change rate is suppressed to be less than 20% by mass in addition to being soluble or swelling to both HFIP and m-cresol and exhibiting high adhesiveness to the housing.

The above test results indicate that high sealability can be maintained even in an environment where a high temperature is reached and the sealing material contacts the lubricating oil, by using a material soluble or swelling to both HFIP and m-cresol and having an oil resistance mass change rate of less than 20% by mass as a sealing material when the sealing material is arranged between a terminal and a housing to improve sealability in an electrical connection member.

Although the embodiment of the present disclosure has been described in detail above, the present invention is not limited to the above embodiment at all and various changes can be made without departing the gist of the present invention.

### LIST OF REFERENCE NUMERALS

1 terminal block (electrical connection member)
2 terminal (busbar)
2a copper plate
2b model terminal
3 housing
3a resin plate
3b housing
31 flange portion
32 holding portion
4 sealing material
4a sheet body of sealing material
4b sealing material
5 rubber ring
A compressed air
B bubble
P adhesion test piece
P′ sealing test piece
S1 outer space
S2 inner space
T tube
W water

1. An electrical connection member, comprising:
a terminal;
a housing for holding the terminal; and
a sealing material arranged between the terminal and the housing,
the housing containing at least one of a polyester-based resin and a polyamide-based resin, and
the sealing material containing a thermoplastic polymer, being soluble or swelling to both hexafluoroisopropanol and m-cresol and having a mass change rate of less than 20% when being immersed in lubricating oil at 100° C. for 8 hours.

2. The electrical connection member of claim 1, wherein a melting point of the sealing material is 150° C. or higher.

3. The electrical connection member of claim 1, wherein the sealing material contains a thermoplastic elastomer as the thermoplastic polymer.

4. The electrical connection member of claim 1, wherein the sealing material contains at least one of a polyurethane-based resin, a polyester-based resin and a polyamide-based resin as the thermoplastic polymer.

5. The electrical connection member of claim 1, wherein the housing contains at least one of a polybutylene terephthalate, a nylon 6T and a nylon 9T.

6. The electrical connection member of claim 1, wherein the electrical connection member is configured as a terminal block for a motor.
